(19) United States
(12) Patent Application Publication
(10) Pub. No.: US 2009/0117731 A1
(43) Pub. Date: May 7, 2009

(54) SEMICONDUCTOR INTERCONNECTION STRUCTURE AND METHOD FOR MAKING THE SAME

(75) Inventors: Chen-Hua Yu, Hsinchu City (TW); Shau-Lin Shue, Hsinchu City (TW); Chien-Hsueh Shih, Taipei City (TW); Ming-Shih Yeh, Hsinchu County (TW); Ming-Han Lee, Taipei City (TW)

Correspondence Address: WPAT, PC;INTELLECTUAL PROPERTY ATTORNEYS, 2030 MAIN STREET, SUITE 1300, IRVINE, CA, 92614, US

(73) Assignee: TAIWAN SEMICONDUCTOR MANUFACTURING CO., LTD., Hsinchu (TW)

(21) Appl. No.: 11/934,005

(22) Filed: Nov. 1, 2007

(51) Int. Cl. H01L 21/4763

(52) U.S. Cl. 438/627; 257/E21.495

(57) ABSTRACT

A semiconductor interconnection structure is manufactured as follows. First, a substrate with a first dielectric layer and a second dielectric layer is formed. Subsequently, an opening is formed in the second dielectric layer. A thin metal layer and a seed layer are formed in sequence on the surface of the second dielectric layer in the opening, wherein the metal layer comprises at least one metal species having phase segregation property of a second conductor. The wafer of the substrate is subjected to a thermal treatment, by which most of the metal species in the metal layer at a bottom of the opening is diffused to a top surface of the second conductor to form a metal-based oxide layer. Afterwards, the wafer is subjected to planarization, so as to remove the second conductor outside the opening.

### BACKGROUND OF THE INVENTION

(A) Field of the Invention

The present invention relates to a semiconductor structure and method for making the same, and more specifically, to a semiconductor interconnection structure and method for making the same.

(B) Description of Related Art

As CMOS transistor scaling proceeds into the deep sub-micron regime, the electrical resistance and parasitic capacitance associated with these metal interconnections have become major factors that limit the circuit speed of such high performance ICs. U.S. Pat. Nos. 7,193,327, 7,176,571, 7,125,791, 6,979,625, 7,186,643, 7,205,228, and U.S. Publication Nos. 2007/0059502, 2006/0076244 and 2003/0010645 disclosed the developments for the metal interconnection process.

FIG. 1 shows a known dual damascene interconnection structure 10. A copper (Cu) line 11 is formed in a base material 12 and a diffusion barrier layer 13 is formed therebetween. A via 14 and a trench 15 are formed in intermetal dielectric layers (IMD) 16 and 17, respectively. Etch stop layers 18 and 19 are formed to protect the copper line 11 and the trench bottom when the dielectric layers 16 and 17 are etched to form the via 14 and the trench 15, respectively. A diffusion barrier layer 20 such as tantalum nitride (TaN) is formed on the sidewalls of the via 14 and the trench 15 by physical vapor deposition (PVD) or atomic layer deposition (ALD). Copper 21 is filled in the via 14 and the trench 15 and followed by a planarization process.

For cases where the diffusion barrier 20 is formed by PVD technology, a via bottom punch-through process is required to reduce via resistance. However, the punch-through process damages via and trench bottom profiles. Nevertheless, the via bottom still has diffusion barrier remaining, i.e., the via bottom is still not diffusion barrier layer free; therefore the resistance between the lower copper line 11 and upper copper 21 is high.

For cases where the diffusion barrier layer 20 is formed by ALD technology, the ALD diffusion barrier layer 20 is thin and conformal. However, the via bottom is still not diffusion barrier layer free; therefore the resistance between the lower copper line 11 and upper copper 21 is high also.

FIGS. 2(a) through 2(c) show a process for making an interconnection structure disclosed in a paper: T. Usui et al., “Low Resistive and Highly Reliable Cu Dual-Damascene Interconnection Technology Using Self-Formed MnSi_{X}O_{Y} Barrier Layer,” IEEE 2005, page 188. A dielectric layer 22 is formed on a copper layer 24 with a barrier layer 25. After lithography and etching for a via and an upper level interconnection, i.e, a trench, in the dielectric layer 22, a copper-manganese (Cu—Mn) alloy layer 23 is sputtered onto the dielectric layer 22 without depositing the barrier metal such as Ta or TaN. Subsequently, a Cu layer 26 is deposited by electro-chemical plating (ECP). After deposition of the Cu—Mn alloy layer 23 and the Cu layer 26, the wafer having such structure is annealed at 300° C. During annealing, Mn atoms in the Cu—Mn alloy layer 23 migrate outside and react with silicon oxide (SiO₂) in the dielectric layer 22, resulting in the formation of a barrier layer 27 of manganese silicon oxide (MnSi_{X}O_{Y}). The remaining Mn atoms in the Cu—Mn alloy layer 23 migrate toward the top surface of the Cu layer 26 to form a manganese oxide (MnO₂) layer on the surface of the Cu layer 26. Afterwards, the Cu layer 26 is planarized by chemical mechanical polishing. As semiconductor devices rapidly become smaller in nano-generations, the Cu—Mn alloy is difficult to accurately deposit on the surface of the dielectric layer 22 by sputtering or physical vapor deposition; thus uniform thickness of the Cu—Mn alloy layer 23 is not easily controlled, which makes the process impractical.

### SUMMARY OF THE INVENTION

These and other problems are generally solved or circumvented, and technical advantages are generally achieved, by advantageous embodiments of the present invention, which provides a method for making a semiconductor interconnection structure that can decrease the interconnection resistance, e.g., via resistance or line resistance, as well as to reducing the manufacturing cost.

The semiconductor interconnection structure in accordance with an embodiment of the present invention comprises a substrate having a first dielectric layer and a second dielectric layer, a first conductor, a diffusion barrier layer and a second conductor. The first conductor such as copper is formed in the first dielectric layer. The second dielectric layer such as a low-k material is formed on the first dielectric layer, and an opening is formed in the second dielectric layer. For an interconnection structure of dual damascene, the opening includes a via portion and a trench portion. For an interconnection structure of single damascene, the opening includes a trench portion. The diffusion barrier layer such as manganese-based oxide or manganese-based silicon oxide is formed on the sidewalls of the second dielectric layer in the opening, and is a product of metal species, e.g., manganese, having phase segregation property reacting with the second dielectric layer. The second conductor such as copper is substantially filled in the opening, and substantially no diffusion barrier layer exists between the first conductor and the second conductor.

According to an embodiment of the present invention, the semiconductor interconnection structure is manufactured as follows. First, a substrate with a first dielectric layer and a second dielectric layer is formed. Subsequently, an opening is formed in the second dielectric layer. A metal layer and a seed layer are formed in sequence on the surface of the second dielectric layer in the opening, wherein the metal layer comprises at least one metal species having phase segregation property of a second conductor. The wafer of the substrate is subjected to a thermal treatment, by which most of the metal species in the metal layer at a bottom of the opening is diffused to a top surface of the second conductor to form a metal-based oxide layer, and as a consequence, there is substantially no diffusion barrier on the bottom of the opening. Afterwards, the wafer is subjected to planarization, so as to remove the second conductor outside the opening.

The first and second conductors are in direct contact, so the metal interconnection resistance can be significantly reduced. Accordingly, the device performance and production yield can be improved.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The advantages of the present invention will become apparent upon reading the following description and upon reference to the accompanying drawings in which:

FIG. 1 illustrates a known dual damascene interconnection structure;

FIGS. 2(a) through 2(c) illustrate a known semiconductor interconnection process; and

FIGS. 3 through 7 illustrate the process for making a semiconductor interconnection structure in accordance with an embodiment of the present invention.

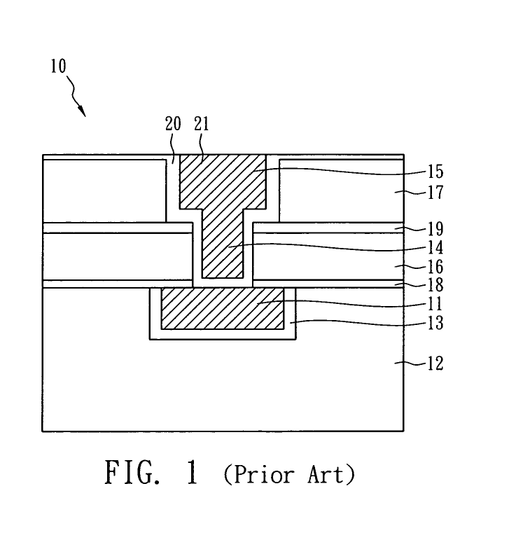

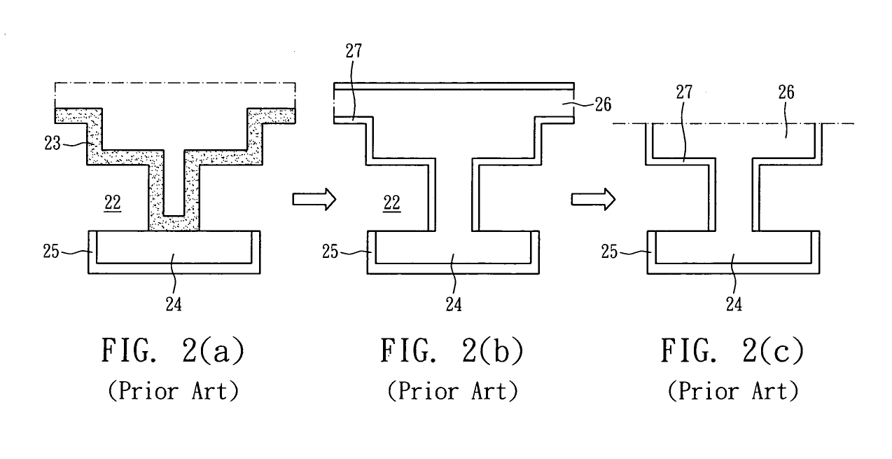

### DETAILED DESCRIPTION OF THE INVENTION

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely, a method for making a semiconductor interconnection structure. The principles of the present invention, however, may also be applied to other semiconductor devices of like construction and integrated circuits, in general.

Embodiments of the present invention provides methods and device designs for decreasing the interconnection resistance. Embodiments of the present invention are described in reference to forming a dual damascene structure with copper therein. Specific shapes and configurations are disclosed, however, it should be appreciated by one of ordinary skill in the art that other shapes and configurations may be used.

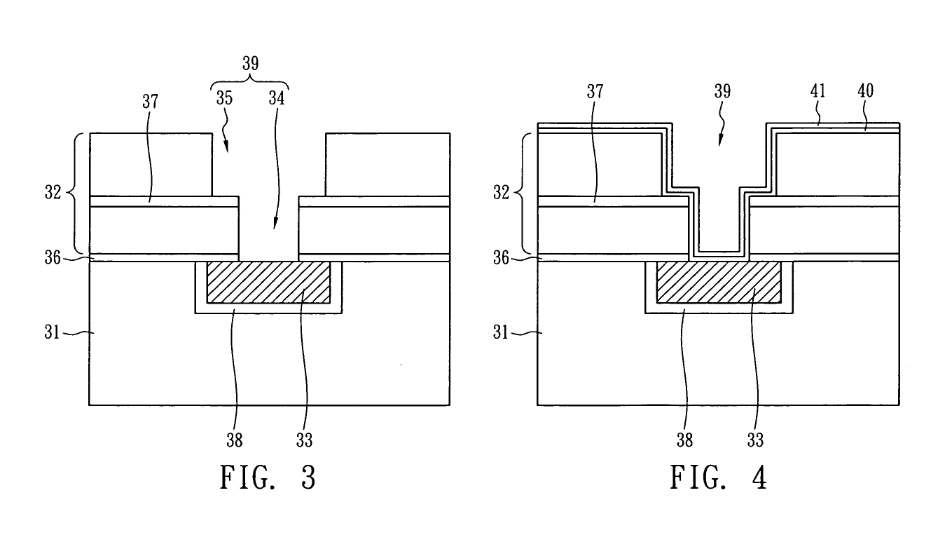

FIGS. 3 through 7 illustrate the method of making a semiconductor interconnection structure in accordance with an embodiment of the present invention.

FIG. 3 illustrates a dual damascene structure with a via portion and a trench portion on a substrate of silicon or silicon-on-insulator (SOI). A first dielectric layer 31 and a second dielectric layer 32 serving as IMD are formed over a silicon substrate or an SOI substrate (not shown) by chemical vapor deposition or spin-on method. In an embodiment, the first dielectric layer 31 or the second dielectric layer 32 comprises low-k dielectric material (dielectric constant k<3), such as carbon-doped oxide, porous low-k and fluorosilicate glass (FSG), and has a thickness of 1000-3500 angstroms. A first conductor 33, e.g., a copper line, with a diffusion barrier layer 38 is formed in the first dielectric layer 31. An opening 39 is formed in the second dielectric layer 32 and includes a via 34 in the lower portion of the second dielectric layer 32, and a trench 35 in the upper portion of the second dielectric layer 32. The via 34 and trench 35 may be formed by dry etching such as reactive etching or plasma etching, which are well known and widely accepted practices by those skilled in the art. In this embodiment, the width of the trench 35 is between 30-60 nanometers, and the diameter of the via 34 is between 20-50 nanometers. The via 34 and the trench 35 can be formed by either “via first” or “trench first” process as desired, which is known by those having ordinary skill in the art. An etch stop layer 36 is formed between the first and second dielectric layers 31 and 32, and another etch stop layer 37 formed in the second dielectric layer serves as a protection layer while the trench 35 is being formed by etching. In this embodiment, the etch stop layer 36 or 37 consists essentially of carbon-containing material like silicon carbide with k<4, and has a thickness between 200-800 angstroms.

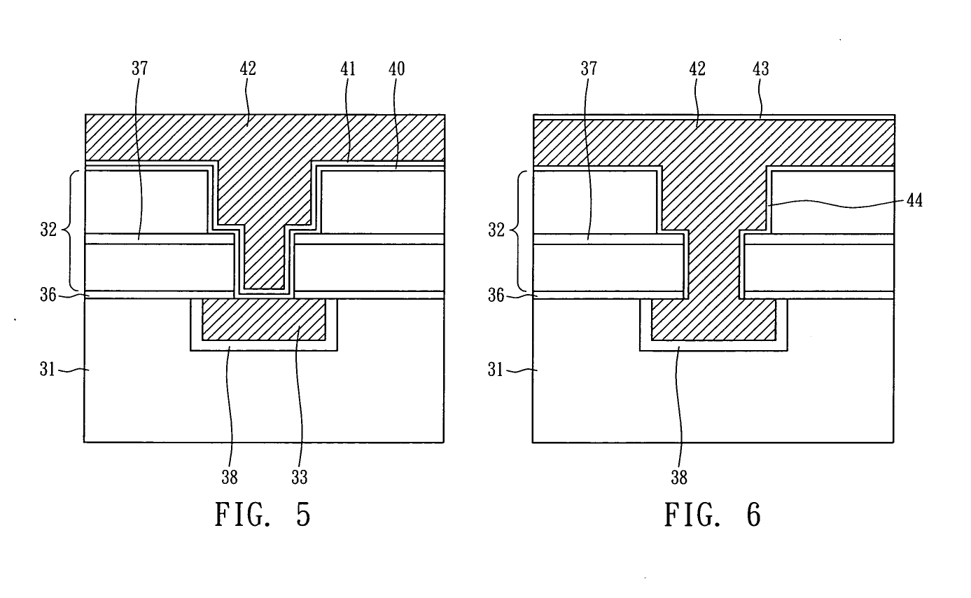

In FIG. 4, a thin metal layer 40 conforming the dual damascene structure including the trench 35 and the via 34 is formed by sputtering, physical vapor deposition (PVD) or chemical vapor deposition (CVD) which are widely used technologies for film formation. The metal layer 40 comprises at least one metal species having segregation property, such as Mn or Mn-containing material. Preferably, the Mn concentration of the metal layer 40 is at least 50%. Generally, thinner metal layer is better, but it is limited to the process tool performance. In a preferred embodiment, the thickness of the metal layer 40 is greater than 10 nanometers. Subsequently, a copper seed layer 41 is formed on the metal layer 40, and the thickness of the copper seed layer 41 is preferably larger than 10 nanometers. Then, the opening 39 is substantially filled with copper by plating technology, e.g., electro-chemical plating, to form a copper layer 42 as shown in FIG. 5. Alternatively, the copper layer 42 can also be formed by electroless copper deposition, so as to provide better film uniformity. However, the shortcoming is that the resistance thereof may be relatively high.

In FIG. 6, the wafer having such damascene structure is subjected to a thermal treatment, e.g., a rapid temperature process (RTP), a flash annealing, a laser annealing or annealing in a furnace, to enable phase segregation by which Mn atoms in the metal layer 40 at the via bottom are diffused to the top surface of the copper layer 42, so that an Mn-based oxide layer 43 is formed on the top surface of the copper layer 42. In a preferred embodiment, the furnace is in an atmosphere including nitrogen, hydrogen, oxygen or their combination. Preferably, the temperature of the thermal treatment is higher than 200° C. Because Mn is sensitive or active to oxygen at a temperature over 200° C., the excess Mn atoms residing at the top surface react with ambient oxygen to form the Mn-based oxide layer 43 during the thermal treatment. The Mn-based oxide layer 43 serving as a capping layer will prevent oxidation of copper in subsequent processes. In an embodiment, the thickness of the Mn-based oxide layer 43 is about 50-300 angstroms according to the time, temperature and oxygen content of the thermal treatment. As a result, the metal layer 40 at the via bottom has substantially disappeared after the thermal treatment.

Meanwhile, Mn atoms in the metal layer 40 also react with adjacent silicon oxide in the dielectric layer 32 like a low-k material of carbon-doped silicon oxide to form a metal-based oxide layer 44 such as manganese oxide (MnO_{X}) or manganese silicon oxide (MnSi_{X}O_{Y}) on the sidewalls of the opening 39. The metal-based oxide layer 44 serves as a diffusion barrier layer and has a thickness between 1-10 nanometers.

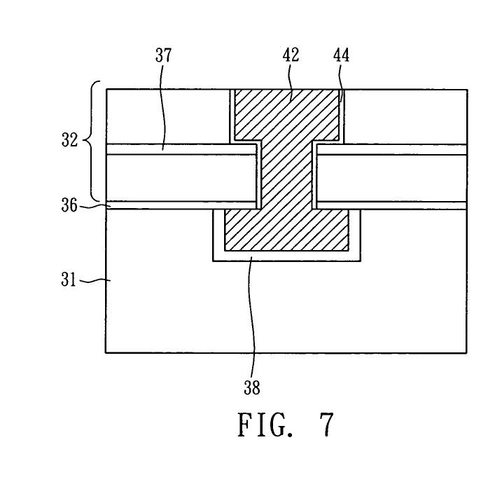

In FIG. 7, the copper layer 42 outside the dual damascene structure is planarized. For example, it is subjected to a chemical mechanical polishing to remove the portion of the copper layer 42 outside the dual damascene.

The present invention disclosed the formation of an Mn/Cu bi-layer before plating of Cu, i.e., the Mn layer is deposited and followed by the deposition of a seed layer. Compared to the prior art disclosed by T. Usui et al., the present method can prevent copper from diffusing to adjacent dielectric before the formation of dielectric diffusion layer on the sidewall of the dual damascene structure.

Owing to the phase segregation, the metal layer at the via bottom has substantially disappeared after the thermal treatment. This will greatly reduce resistance of interconnection. In other words, the copper segments at the via bottom are in direct contact, so that low via resistance (Rc) can be obtained. Moreover, the metal-based oxide layer 44 serving as the diffusion barrier layer is thin and uniform, so that low line resistance (Rs) can be obtained also.

In addition to the dual damascene structure, the same method can also be applied to a single damascene structure of a trench. Chromium (Cr), zirconium (Zr) or magnesium (Mg) can be an alternative for Mn as the base material of the thin metal layer 40. Copper alloy or aluminum also can be a metal for the interconnection conductors 33 and 42.

Also, although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of making a semiconductor interconnection structure, comprising:
providing a first dielectric layer with a first conductor therein and a second dielectric layer, wherein the second dielectric layer is formed on the first dielectric layer;
forming an opening in the second dielectric layer;
forming a metal layer on the surface of the opening, wherein the metal layer comprises at least one metal species having a phase segregation property reacting with a second conductor;
forming a seed layer on the metal layer;
filling the opening by the second conductor;
performing a thermal treatment, by which most of the at least one metal species in the metal layer at the bottom of the opening is diffused to the top surface of the second conductor to form a metal-based oxide layer; and
removing the second conductor outside the opening.

2. The method of claim 1, wherein the opening is formed by a single damascene or a dual damascene.

3. The method of claim 1, wherein the metal layer is formed by sputtering or chemical vapor deposition.

4. The method of claim 1, wherein the metal species has a phase segregation property at a temperature greater than 200° C.

5. The method of claim 1, wherein the metal species is sensitive to oxygen at a temperature higher than 200° C.

6. The method of claim 1, wherein the metal species is selected from the group consisting essentially of manganese, chromium, zirconium and magnesium.

7. The method of claim 1, wherein the metal layer on the sidewall of the opening is reacted with the second dielectric layer so as to form a diffusion barrier layer in the thermal treatment.

8. The method of claim 1, wherein the thermal treatment is performed at a temperature higher than 200° C.

9. The method of claim 1, wherein the thermal treatment is a rapid temperature process, flash annealing, laser annealing or annealing in a furnace.

10. The method of claim 1, wherein the first conductor and the second conductor comprise one of copper, aluminum and copper alloy.

11. A method of making a semiconductor interconnection structure, comprising:
providing a dual damascene structure;
forming a metal layer conforming the dual damascene structure, wherein the metal layer comprises at least one metal species having a phase segregation property reacting with a conductor;
forming a seed layer on the metal layer;
filling the dual damascene structure by the conductor;
performing a thermal treatment, by which most of the at least one metal species in the metal layer at the bottom of the dual damascene structure is diffused to the top surface of the conductor to form a metal-based oxide layer; and
removing the conductor outside the dual damascene structure.

12. The method of claim 11, wherein the metal species is selected from the group consisting essentially of manganese, chromium, zirconium and magnesium.

13. The method of claim 11, wherein the metal layer on the sidewall of the dual damascene structure is transformed into a diffusion barrier layer in the thermal treatment.

14. The method of claim 11, wherein the thermal treatment is performed at a temperature higher than 200° C.

15. The method of claim 11, wherein the thermal treatment is a rapid temperature process, flash annealing, laser annealing or annealing in a furnace.

16. A method for making a semiconductor interconnection structure, comprising:
providing a dielectric layer including an opening;
forming a metal layer conforming the opening, wherein the metal layer comprises at least one metal species having a phase segregation property reacting with a conductor;
forming a seed layer on the metal layer;
filling the opening by the conductor;
performing a thermal treatment, by which most of the at least one metal species in the metal layer at the bottom of the opening is diffused to the top surface of the conductor to form a metal-based oxide layer; and
removing the conductor outside the opening.

17. The method of claim 16, wherein the metal species is selected from the group consisting essentially of manganese, chromium, zirconium and magnesium.

18. The method of claim 16, wherein the metal layer on the sidewall of the opening is reacted with the dielectric layer so as to form a diffusion barrier layer in the thermal treatment.

19. The method of claim 16, wherein the thermal treatment is performed at a temperature higher than 200° C.

20. The method of claim 16, wherein the thermal treatment is a rapid temperature process, flash annealing, laser annealing or annealing in a furnace.
